(19) United States
(12) Patent Application Publication
(10) Pub. No.: US 2022/0366095 A1
(43) Pub. Date: Nov. 17, 2022

(54) METHOD AND APPARATUS FOR CHECKING AND/OR CONFIGURING THE ARRANGEMENT OF THE PHYSICAL ELEMENTS OF A VEHICLE

(71) Applicant: ITALDESIGN-GIUGIARO S.P.A., Torino (IT)

(72) Inventors: Fabrizio RIBET, Bricherasio (Torino) (IT); Elena Flaminia Dirce TAMMARO, Torino (IT); Marco VALSANIA, Moncalieri (Torino) (IT); Matilde PICCIONI, Sinalunga (Siena) (IT); Remo GORIANZ, Torino (IT); Roberto FORLIN, Torino (IT); Vincenzo BELMONTE, Torino (IT)

(21) Appl. No.: 17/762,422

(22) PCT Filed: Sep. 29, 2020
(86) PCT No.: PCT/IB2020/059089

§ 371 Date: Mar. 22, 2022

(30) Foreign Application Priority Data
Sep. 30, 2019 (IT) 102019000017573

(51) Int. Cl. G06F 30/15; G06F 30/20

(52) U.S. Cl. CPC G06F 30/15; G06F 30/20

(57) ABSTRACT

A method for checking and/or configuring the arrangement of physical elements of a vehicle includes providing a test apparatus configured to simulate the arrangement of the physical elements of the vehicle and having a support structure to which one or more physical elements are joined, adjustable relative to the support structure, acquiring or processing a virtual model representative of an arrangement of the one or more physical elements relative to the support structure and physically positioning the one or more physical elements according to the virtual model arrangement, defining a first reference point, a position of the first reference point relative to the support structure being known, and measuring a relative distance between the first reference point and a second reference point on a virtual reality viewer, interfacing a user with an electronic processing unit, and acquiring and transmitting data indicative of the user's movements to the electronic processing unit.

### TECHNICAL FIELD

This invention is generally in the field of test methods and apparatuses; in particular, the invention relates to a method and an apparatus for checking and/or configuring the arrangement of the physical elements of a vehicle.

### PRIOR ART

Test apparatuses are known for adjusting the arrangement of the physical parts of a vehicle passenger compartment which exploit the interaction with a virtual environment projected in 2D on walls external to the vehicle mock-up to simulate the real conditions of use.

An example of this apparatus is known from US 2015/0228199, which illustrates a platform comprising a plurality of movable parts, around which it is possible to generate, by means of projectors, a virtual scene, representative of the conditions outside the passenger compartment.

An apparatus according to the aforesaid prior art document allows the position of the various physical elements constituting the apparatus so as to configure the latter in a predetermined operating position.

Nevertheless, the test equipment according to the aforesaid document does not allow the correspondence of this configuration, resulting from the adjustment procedure of the physical elements, with the structure and the operating conditions of a real vehicle to be fully evaluated, nor does it allow a sufficiently immersive virtual environment to be generated so that the simulation experience may extend to the widest possible variety of real vehicle configurations (for example, by fully replicating the interior of the passenger compartment, i.e. also reproducing its features such as finishes, colors, or vehicle components not physically included in the test apparatus).

These factors, understandably, limit the concrete overlap between the test conditions and the real use conditions of the vehicle.

To overcome these drawbacks, the prior art contemplates a plurality of solutions intended to superimpose a virtual scene on a real environment, such as the passenger compartment of a vehicle. Examples of such solutions are known from documents DE 10 2015 003884 A1, U.S. Pat. No. 7,761,269 B1 and EP 1 533 683 A2, wherein the superimposition of the virtual and real environments is carried out by photogrammetric detection of the movement of a plurality of markers distributed on the body of the user (using the so-called “motion capture” technique).

Such an approach is characterized by the absence of an extrinsic reference system, as the movement and arrangement of physical entities is simulated on the basis of the positions that these entities assume directly in the virtual scene. In effect, the position of the physical bodies at a given instant is recorded by means of optical devices that capture the position of the markers associated with these physical elements, and the resulting signals from the optical devices are projected onto a virtual grid or background, so that the movement of the physical bodies is detected as the difference between the position that the markers assume in two different instants relative to this virtual background, which thus constitutes an intrinsic reference system.

The absence of a methodology for assigning an extrinsic reference system entails an increase in the computational cost of the simulation, because it makes it more complex to align the physical environment with the virtual scene.

### SUMMARY OF INVENTION

An object of this invention is to overcome the aforementioned problems.

To obtain this result, a method according to this invention provides the steps for preparing a test apparatus, comprising one or more physical elements adjustable in position and/or orientation, predetermining a specific configuration thereof (which is to be subjected to a test to evaluate the features thereof such as ergonomics, design conformity, aesthetic performance, etc., with reference, for example, to the configurations of sports and commercial vehicles, etc.), by processing or acquiring a virtual model by means of an electronic processing unit.

Then, the physical elements of the apparatus are adjusted, until their position and/or their orientation coincide with those that the same elements have in the virtual model.

Subsequently, a user of the vehicle is interfaced with this electronic processing unit by means of a virtual reality viewer, which allows the user to immerse himself completely in the virtual model.

This would also make it possible to recreate and model the real vehicle almost entirely in the virtual environment, including those parts of the vehicle that do not have physical correspondents in the test apparatus (for example, a dashboard contoured according to a certain shape, when perhaps the test apparatus does not have an equivalent element) and/or to which one wishes to impart features (such as colors and finishes) that the corresponding physical parts of the test apparatus do not have.

The method further provides for defining a first reference point, the position of which is known in the physical environment, and measuring its distance from the second reference point on the viewer, after which the user's point of view is positioned on the viewer, according to that distance.

In this way, the user's view is linked to the virtual model, and, consequently, the portion that the user will see of the virtual model will depend on the real movements of his head.

The aforesaid and other objects and advantages are achieved, according to an aspect of the invention, by a method and an apparatus having the features defined in the appended claims.

### BRIEF DESCRIPTION OF THE DRAWINGS

The functional and structural features of some preferred embodiments of a method and an apparatus according to the invention will now be described. Reference is made to the accompanying drawings, wherein:

FIG. 1 is a schematic perspective view of a test apparatus, according to an embodiment of this invention;

FIG. 2 is a schematic side view of the test apparatus in FIG. 1;

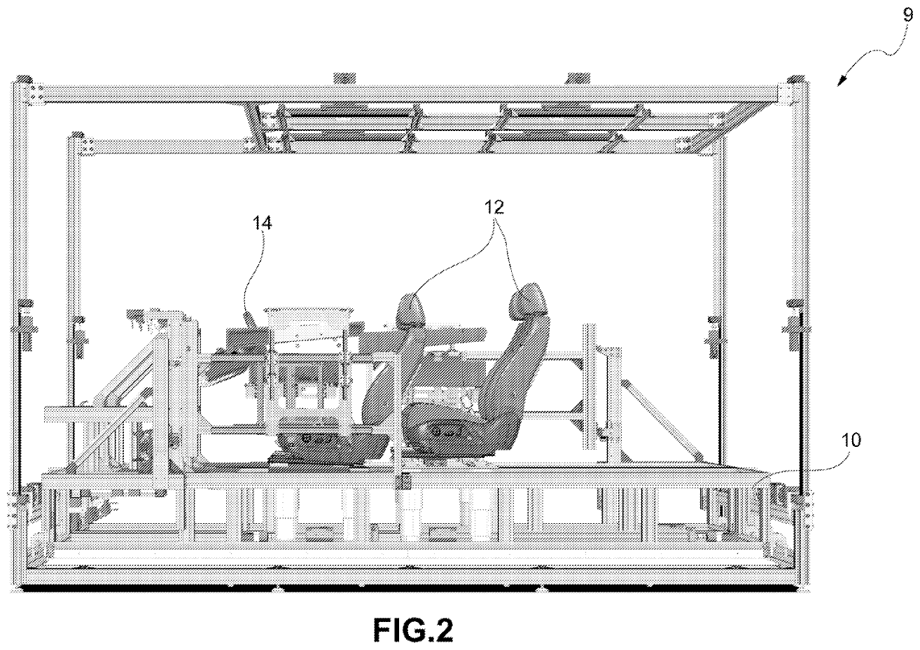

FIGS. 3A and 3B are respectively a side schematic view of a seat that may be incorporated into the test apparatus, and an enlargement of this seat, according to an embodiment of this invention;

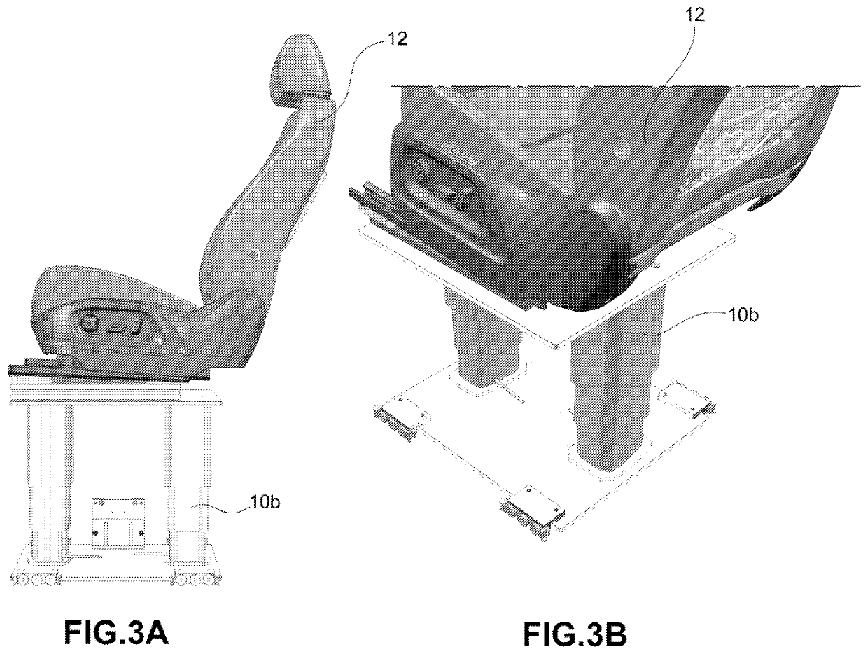

FIG. 4 is a schematic perspective view of a steering wheel that may be incorporated into the test apparatus, according to an embodiment of this invention;

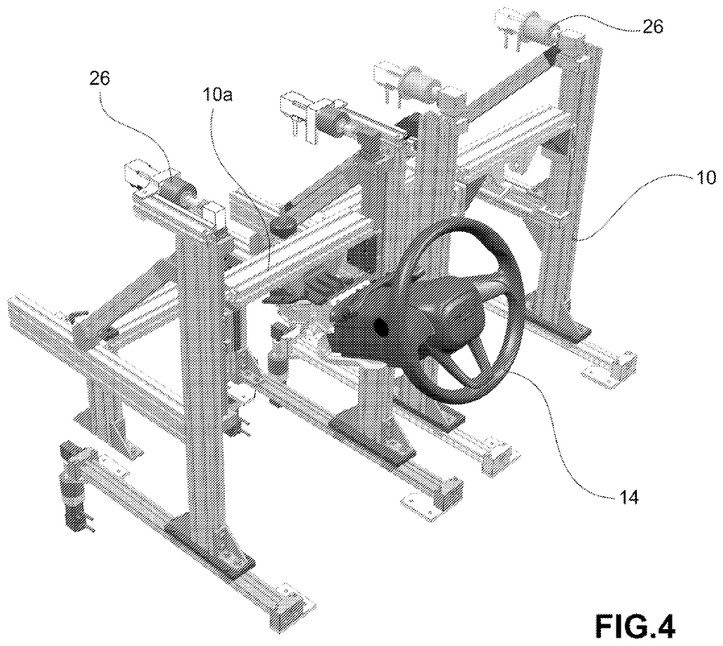

FIGS. 5A and 5B are respectively a schematic perspective view of a structure (which may be incorporated into the test apparatus) which simulates the roof of a vehicle, and of an enlargement of this structure, according to an embodiment of this invention;

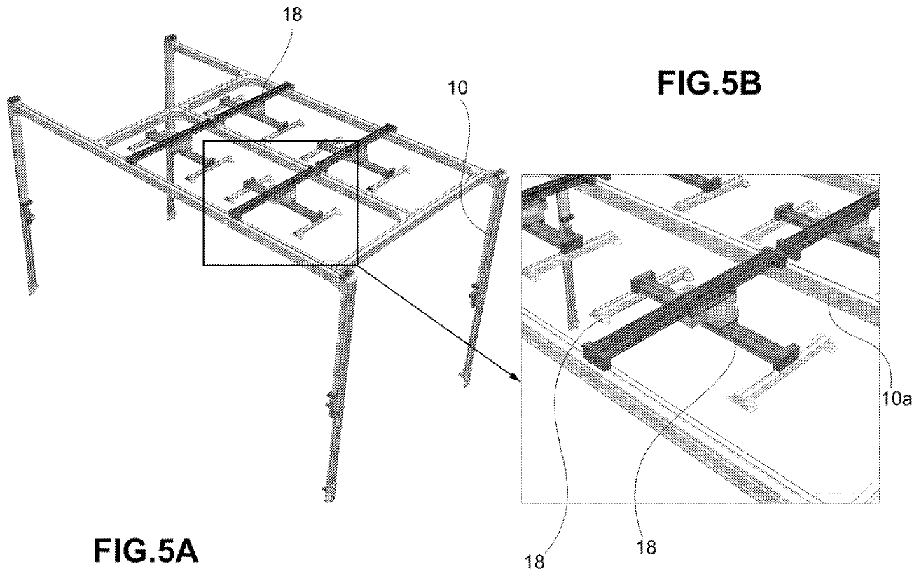

FIG. 6A to 6D are respectively a schematic perspective view of a pedalboard, which may be incorporated into the test apparatus, and of a plurality of enlargements of this pedalboard, according to an embodiment of this invention; and

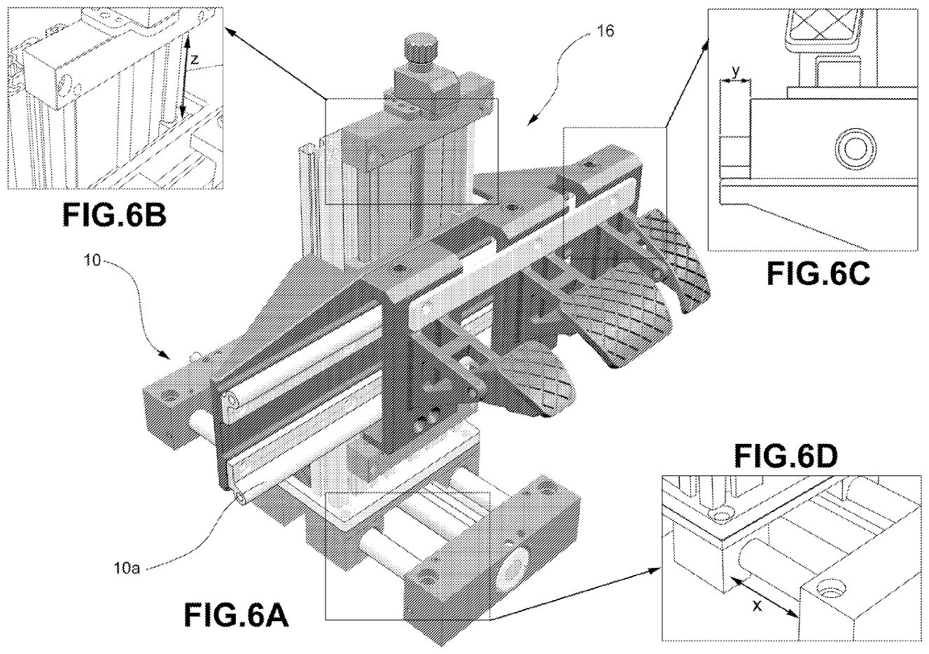

FIG. 7A to 8B are schematic views of steps of the method for checking and/or configuring the arrangement of the physical elements of a vehicle, wherein parts of the test apparatus are positioned as reference points (respectively, a point indicative of a standard position of the user's heel, a point indicative of a position of the user's foot, and a point indicative of a rearmost and lowermost position of a seat relative to the front of the vehicle), so that positions and/or orientations of these parts of the apparatus, relative to the support structure of the test apparatus, coincide with the positions and/or orientations that these parts of the apparatus have in a pre-processed or pre-acquired virtual model, according to an embodiment of the invention.

### DETAILED DESCRIPTION

Before describing in detail a plurality of embodiments of the invention, it should be clarified that the invention is not limited in its application to the construction details and configuration of the components presented in the following description or illustrated in the drawings. The invention is capable of assuming other embodiments and of being implemented or constructed in practice in different ways. It should also be understood that the phraseology and terminology have a descriptive purpose and should not be construed as limiting.

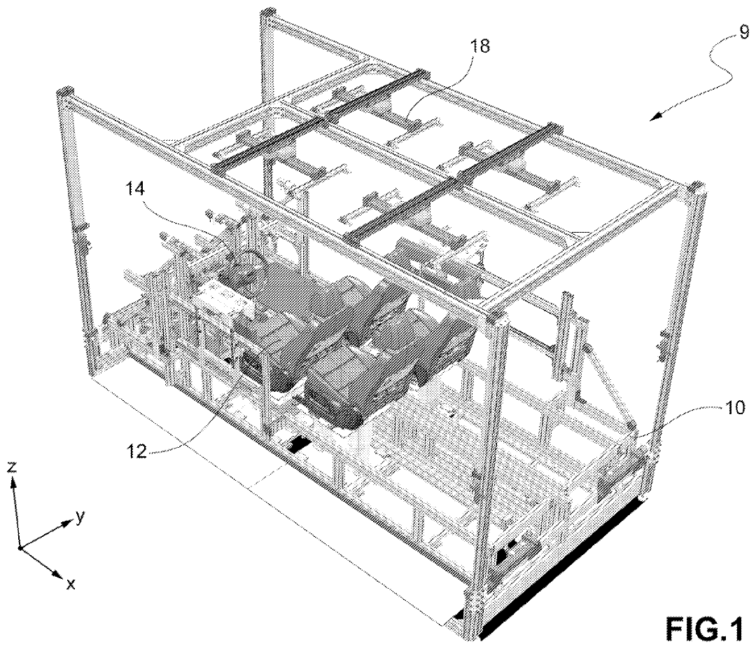

Referring by way of example to FIG. 1, a method for checking and/or configuring the arrangement of the physical elements of a vehicle comprises the steps of preparing a test apparatus 9, adapted to simulate the arrangement of the physical elements of the vehicle.

This test apparatus 9 comprises a support structure 10, to which one or more physical elements 12, 14, 16, 18, 20, 22 are joined, the position and/or orientation of which are adjustable with respect to the support structure 10.

Said physical elements 12, 14, 16, 18, 20, 22 comprise at least a seat 12, and/or a steering wheel 14, and/or a pedalboard 16, and/or a roof 18, and/or at least one door, and/or an armrest for a user of the test apparatus 9, and/or a compartment used as a trunk.

The method further comprises the step of:
acquiring or processing, by means of an electronic processing unit, a virtual model representative of an arrangement of the one or more physical elements 12, 14, 16, 18, 20, 22 relative to the support structure 10 of the test apparatus; arranging the one or more physical elements 12, 14, 16, 18, 20, 22 according to said arrangement, in such a way that the position and/or orientation of said one or more physical elements 12, 14, 16, 18, 20, 22 relative to the support structure 10 coincide with the position and/or orientation of the corresponding one or more physical elements in said virtual model;
interfacing said user with said electronic processing unit by means of a virtual reality viewer, wherein the aforesaid virtual model is displayed from a given point of view POV; acquiring and transmitting data indicative of the user's movements to said electronic processing unit.

In this way, the user will have the opportunity to completely immerse himself in the virtual environment, and to evaluate the ergonomic, structural and aesthetic conformity of the vehicle being tested.

The virtual model may be processed or acquired using, for example, a CAD/CAE/CAM platform.

The method further comprises the steps of:
defining a first reference point, the position of which relative to the support structure 10 is known; measuring a relative distance between said first reference point and a second reference point on the viewer; and
positioning, through said processing unit, the POV point of view of the viewer as a function of this relative distance.

According to an embodiment, the aforesaid step of arranging the one or more physical elements 12, 14, 16, 18, 20, 22, in such a way that their position and/or orientation coincide with the position and/or orientation of the corresponding one or more physical elements in said virtual model is performed by moving the one or more physical elements 12, 14, 16, 18, 20, 22 as a function of their distance from one or more predetermined reference points P, O, H, identified relative to the support structure 10, until the position and/or orientation of one or more physical elements 12, 14, 16, 18, 20, 22 coincide with the position and/or orientation that these parts of the apparatus have in the pre-processed or pre-acquired virtual model.

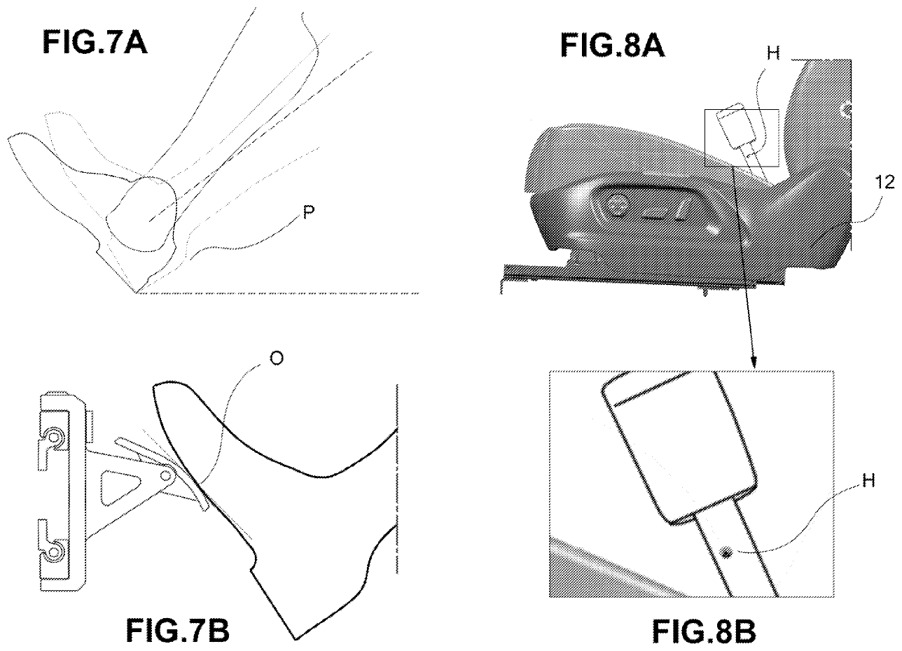

For example, the one or more physical elements 12, 14, 16, 18, 20, 22 may be moved until their position and/or orientation determine a specific arrangement of a user's heel relative to a heel point P, indicative of a standard position of the user's heel (as illustrated by way of example in FIG. 7A), and/or until their position and/or orientation determine a specific disposition of the user's foot relative to a heel point O, indicative of a position of the user's foot (as illustrated by way of example in FIG. 7B), and/or until their position and/or orientation determine a specific arrangement of a seat 12 relative to a seat point H, indicative of a rearmost and lowermost position of the seat relative to the front part of the vehicle (as illustrated by way of example in FIGS. 8A and 8B). The position of such reference points P, O, H is generally predetermined according to conventional type-approval specifications.

Expediently, there is also the step, using said electronic processing unit, of processing the aforesaid virtual model and obtaining an integrated virtual model further comprising virtual elements, representative of elements inside and/or outside the vehicle, to simulate a real use condition of the vehicle. This step may be obtained, for example, by using a virtual rendering and prototyping software, such as the program commercially known as the acronym VRED™, distributed by Autodesk.

According to an embodiment, the method further comprises the step of:
interfacing the user with a plurality of wearable sensors, each capable of transmitting a signal representative of its position and/or movement in space. It is possible to carry out this step, for example, by means of a photogrammetric system, by means of a so-called “motion capture” device, known per se.

According to an embodiment, the aforesaid step of arranging the physical elements 12, 14, 16, 18, 20, 22, according to the position and/or orientation assumed thereby in the virtual model, is carried out by means of electromechanical adjustment.

Moreover, a test apparatus 9 for checking the arrangement of the physical elements of a vehicle comprises a support structure 10 to which the one or more physical elements 12, 14, 16, 18, 20, 22 are joined, the position and/or orientation of which are adjustable relative to the support structure 10, these physical elements comprising at least a seat 12, and/or a steering wheel 14, and/or a pedalboard 16, and/or a roof 18, and/or at least one door, and/or an armrest for a user of the test equipment, and/or a compartment used as a trunk; an electronic processing unit, configured to acquire or process the virtual model representative of an arrangement of the one or more physical elements 12, 14, 16, 18, 20, 22 relative to the support structure 10 of the test apparatus 9; a virtual reality viewer, adapted to view said virtual model from a given point of view POV; and acquisition and transmission means adapted, respectively, to acquire and transmit data indicative of the user's movements to said electronic processing unit. The electronic processing unit is configured to position the viewer's point of view POV as a function of a relative distance between a first reference point, the position of which relative to the support structure 10 is known, and a second reference point on the viewer.

According to an embodiment, said acquisition means comprise a plurality of wearable sensors (not shown), each adapted to transmit a signal representative of its position and/or its movement in space.

Expediently, the test apparatus 9 further comprises electromechanical adjustment means 26, adapted to adjust the position and/or orientation of the one or more internal physical elements 12, 14, 16, 18, 20, 22 relative to the support structure 10.

Preferably, the support structure 10 comprises rails 10a and/or telescopic columns 10b adapted to slidingly and/or pivotally support the one or more physical elements of the vehicle 12, 14, 16, 18, 20, 22.

According to a preferred embodiment, said electronic processing unit is further configured to process said virtual model to obtain an integrated virtual model further comprising virtual elements, representative of elements inside and/or outside the vehicle.

Various aspects and embodiments of a method and apparatus for checking and/or configuring the arrangement of the physical elements of a vehicle have been described, according to the invention. It is understood that each embodiment may be combined with any other embodiment. Furthermore, the invention is not limited to the described embodiments, but may be varied within the scope defined by the appended claims.

1-11. (canceled)

12. A method for checking and/or configuring an arrangement of physical elements of a vehicle, said method comprising the steps of:
a) providing a test apparatus configured to simulate the arrangement of the physical elements of the vehicle, said test apparatus comprising a support structure to which one or more physical elements are associated, a position and/or an orientation of said one or more physical elements being adjustable relative to the support structure, said physical elements comprising at least one of a pedalboard, a seat, a steering wheel, a roof, a door, an armrest for a user of the test apparatus, a trunk compartment;
b) acquiring or processing, by an electronic processing unit, a virtual model representative of an arrangement of the one or more physical elements relative to the support structure of the test apparatus;
c) arranging the one or more physical elements in such a way that the position and/or the orientation of said one or more physical elements relative to the support structure coincide with the position and/or the orientation of a corresponding one or more physical elements in said virtual model;
d) interfacing said user with said electronic processing unit by a virtual reality viewer, wherein the acquired or processed virtual model is displayed from a given point of view; and
e) acquiring, and transmitting to said electronic processing unit, data indicative of movements of the user;
wherein step c) comprises:
c1) defining a first reference point, a position of said first reference point relative to the support structure being known;
c2) measuring a relative distance between said first reference point and a second reference point, said second reference point being on the virtual reality viewer; and
c3) positioning, through said electronic processing unit, the point of view of the virtual reality viewer depending on the relative distance measured step c2); and
wherein step c) is carried out by moving the one or more physical elements as a function of a distance of said one or more physical elements from one or more pre-determined reference points, identified relative to the support structure, until the position and/or the orientation of the one or more physical elements coincides with the position and/or the orientation of said one or more physical elements in the acquired or processed virtual model, said one or more physical elements being moved until the position and/or the orientation thereof determines a specific disposition of a user's heel relative to a heel point, indicative of a standard position of the user's heel.

13. The method of claim 12, further comprising:
f) processing, by said electronic processing unit, the virtual model acquired in step b) and obtaining an integrated virtual model further comprising virtual elements, representative of elements inside and/or outside the vehicle, to simulate a real use condition of the vehicle.

14. The method of claim 12, further comprising:
g) interfacing said user with a plurality of wearable sensors, each one adapted to transmit a signal representative of its position and/or motion in space.

15. The method of claim 12, wherein step c) is carried out by electro-mechanical adjustment.

16. A test apparatus for checking an arrangement of physical elements of a vehicle, the test apparatus comprising:
a support structure joined to one or more physical elements, a position and/or an orientation of said one or more physical elements being adjustable relative to the support structure, said physical elements comprising at least one of a seat, a steering wheel, a pedalboard, a roof, a door, an armrest for a user of the test apparatus, a trunk compartment;
an electronic processing unit configured to acquire or process a virtual model representative of an arrangement of the one or more physical elements relative to the support structure of the test apparatus;
a virtual reality viewer configured to display said virtual model from a given point of view; and
acquisition and transmission means configured respectively to acquire and transmit data, indicative of movements of the user, to said electronic processing unit;
wherein said electronic processing unit is configured to position the point of view of the virtual reality viewer according to a relative distance between a first reference point, a position of said first reference point relative to the support structure being known, and a second reference point on the virtual reality viewer.

17. The test apparatus of claim 16, wherein said acquisition and transmission means comprise a plurality of wearable sensors, each one configured to transmit a signal representative of its position and/or motion in space.

18. The test apparatus of claim 16, further comprising electromechanical adjustment means for adjusting the position and/or the orientation of the one or more physical elements relative to the support structure.

19. The test apparatus of claim 16, wherein the support structure comprises rails and/or telescopic columns configured to slidingly and/or pivotally support the one or more physical elements of the vehicle.

20. The test apparatus of claim 16, wherein said electronic processing unit is further configured to process said virtual model to obtain an integrated virtual model further comprising virtual elements, representative of elements inside and/or outside the vehicle.
